(19) United States
(12) Patent Application Publication
(10) Pub. No.: US 2026/0198315 A1
(43) Pub. Date: Jul. 9, 2026

(54) COLD PLATE WITH MATCHED COEFFICIENT OF THERMAL EXPANSION

(71) Applicant: Analog Power Conversion LLC, Bend, OR (US)

(72) Inventors: Wang-Chang A. GU, Bend, OR (US); Su-Wen Chen, Bend, OR (US); Dumitru Gheorge Sdrulla, Bend, OR (US); Amaury Gendron, Bend, OR (US)

(21) Appl. No.: 19/009,217

(22) Filed: Jan. 3, 2025

(51) Int. Cl. H01L 23/473

(52) U.S. Cl. CPC H10W 40/47

(57) ABSTRACT

An apparatus for cooling a semiconductor die comprises a one or more mechanical substrates mechanically coupled to the die. The substrates are configured to extract thermal energy from the die and to provide electrical insulation to the die. A coefficient of linear thermal expansion (CTE) of the substrates is similar to a CTE of the semiconductor die. The substrates comprise crystalline silicon carbide, which may be single-crystal 4H silicon carbide. A difference between the CTE of the substrates and the CTE of the semiconductor die is 10% or less or is 0.30×10-6/° C. or less over an entire target operating temperature range of the semiconductor device.

### RELATED APPLICATIONS

This application is related to U.S. application Ser. No. 18/941,357 filed on Nov. 8, 2024, titled “Mechanical Substrate with Matched Coefficient of Thermal Expansion.”

### BACKGROUND

Semiconductor dies (hereinafter dies) may be mounted to a substrate. The substrate may provide physical support, carry off heat generated by the dies, and in some cases provide electrical insulation to the semiconductor device. A substrate configured to conduct a substantial amount of heat generated by a die away from the die may be referred to as a “cold plate.”

Over time, dies have grown larger, the power dissipated by dies has increased, on-die and ambient operating temperatures of dies have increased, the size of individual interconnects to a die have decreased, and a maximum number of interconnects to a die have increased.

A die mounted on a substrate may experience a wide range of temperatures over its operating lifetime. For example, the die and substrate may thermal cycle between 25° C. when an apparatus is off or idle, and 500° C. or more when that apparatus is fully on.

As a result, substrates known in the art that have substantially different Coefficients of linear Thermal Expansion (CTEs) relative to the die may decrease the life expectancy of the die. For example, when the CTE of a substrate is substantially different from a die having potentially thousands of small connection points such as solder bumps, and the substrate and die thermal cycle over a large temperature range, the difference in the respective changes in dimensions of the die and the substrate may cause the solder bumps to deform, break, or short together, and may also induce mechanical strain on the die as well, any of which may lead to the die becoming non-operational. The difference in the respective changes in dimensions of the die and the substrate may also cause crack to form in a passivation layer of the die, which may allow contaminants to reach active areas, gate oxides, or high-voltage terminations included in the die, degrading the reliability of the die.

In the past, substrates having CTE different from dies mounted thereon have conventionally been used because the conditions (such as noted above) under which such CTE mismatches could cause device failure were relatively rare. For example, substrates made of Aluminum Nitride (AlN) are commonly used even though they have poor thermal conductivity and CTEs substantially different from common semiconductor dies. Substrates of Silicon Nitride (Si₃N₄) are also used but usually with copper cladding on the top and bottom to improve thermal conductivity, and the copper cladding causes the CTE to be substantially different from common semiconductor dies.

Cold plates, on the other hand, have conventionally comprised materials with good thermal conductivity, such as copper alloys and aluminum alloys. However, such alloys typically have CTEs five or more times the CTEs of dies. Furthermore, in some systems, the cold plate must have high thermal conductivity but be electrically insulated from the dies and/or other components, which requires the use of additional components/materials when the cold plate comprises a metal alloy.

As the conditions under which mismatched CTEs can cause damage become increasingly commonplace and increasingly severe, more situations may arise where such cold plates may not be suitable.

Many materials with CTEs similar to a die may be unsuitable for use as a cold plate because they lack the necessary high thermal conductivity.

Accordingly, it would be advantageous to have a cold plate suitable for use in applications that experience thermal cycling over a wide range of temperatures that would prevent temperature-induced mechanical stress from damaging a die mounted on that substrate while also possessing high thermal conductivity.

### SUMMARY OF THE INVENTION

Embodiments relate to semiconductor packaging, and in particular to cold plates used to transport heat away from semiconductor dies where the cold plates comprise CTE-matched high-thermal-conductivity material such as single-crystal 4H Silicon Carbide (SiC).

In an embodiments, an apparatus for cooling a semiconductor die comprises a first substrate mechanically coupled to the die. The first mechanical substrate is configured to extract thermal energy from the die and to provide electrical insulation to the die. A coefficient of linear thermal expansion (CTE) of the first substrate is similar to a CTE of the semiconductor die. The first substrate comprises crystalline silicon carbide.

In embodiments, a difference between the CTE of the first substrate and the CTE of the semiconductor die is 10% or less over an entire target operating temperature range of the semiconductor device, or is 0.30×10⁻⁶/° C. or less over an operating temperature range of the semiconductor device.

In embodiments, the first substrate comprises single-crystal 4H silicon carbide.

In an embodiment, the apparatus comprises a second substrate mechanically coupled to the semiconductor die and configured to extract thermal energy from the die.

### BRIEF DESCRIPTION OF THE DRAWINGS

FIG. 1A is a cross section of an apparatus for cooling a die using a substrate according to an embodiment.

FIG. 1B is a cross section of an apparatus for cooling a die using a substrate according to another embodiment.

FIG. 1C is a cross section of an apparatus for cooling a die using substrates according to another embodiment.

FIG. 2A is a cross section of an apparatus for cooling a die using a substrate according to an embodiment.

FIG. 2B is a cross section of an apparatus for cooling a die using a substrate according to another embodiment.

FIG. 2C is a cross section of an apparatus for cooling a die using a substrate according to another embodiment.

FIG. 2D is a cross section of an apparatus for cooling a die using a substrate according to another embodiment.

FIG. 3A is a cross section of an apparatus for cooling a die using substrates according to an embodiment.

FIG. 3B is a cross section of an apparatus for cooling a die using substrates according to another embodiment.

FIG. 3C is a cross section of an apparatus for cooling a die using substrates according to another embodiment.

FIG. 4A is a cut-away cross section of an apparatus for cooling a die using a substrate according to another embodiment.

FIG. 4B is a cut-away cross section of an apparatus for cooling a die using a substrate according to another embodiment.

### DETAILED DESCRIPTION

Embodiments of the present application relate to substrates configured to conduct heat away from one or more dies mounted thereon. In particular, embodiments relate to substrates having a Coefficient of linear Thermal Expansion (CTE) substantially similar to the one or more die mounted thereon. The bulk of such a substrate may comprise single-crystal 4H Silicon Carbide (SiC).

A detailed description of embodiments is provided below along with accompanying figures. The scope of this disclosure is limited only by the claims and encompasses numerous alternatives, modifications, and equivalents. Although steps of various processes may be presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

In the remainder of this disclosure, a reference to a “substrate” refers to a cold plate or a component thereof unless otherwise indicated. The illustrated embodiments describe cold plates that support a single die having three electrical connection points (e.g., pads), but embodiments are not limited thereto, and a person of ordinary skill in the art would understand that one or more other kinds of die may be mounted to cold plates according to embodiments.

In the descriptions of the embodiments, the part making up the bulk of a substrate may be referred to as the “substrate”, but a person of ordinary skill in the related arts would understand that “substrate” may also include additional elements (such as insulating layers, conductive elements, protective coatings, and the like) disposed on or in the bulk of the substrate. Unless otherwise indicated, the substrates disclosed herein consist primarily of a material (such as single-crystal 4H SiC) that has a CTE similar to (i.e. “matched”) to a CTE of a semiconductor die.

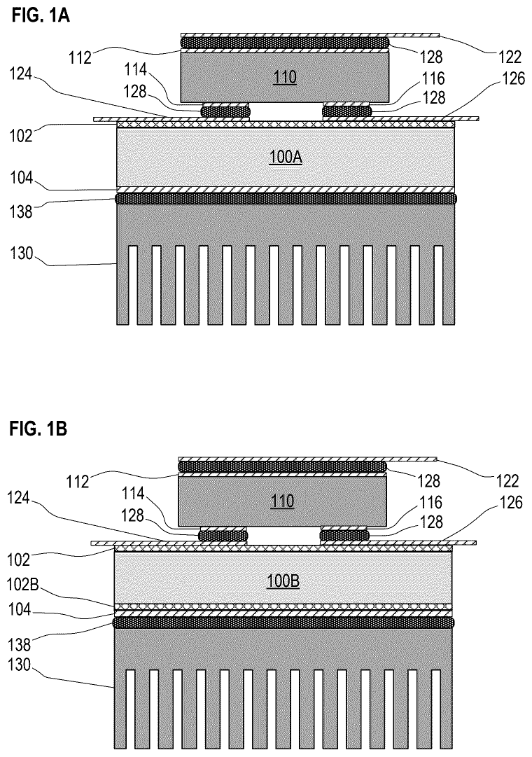

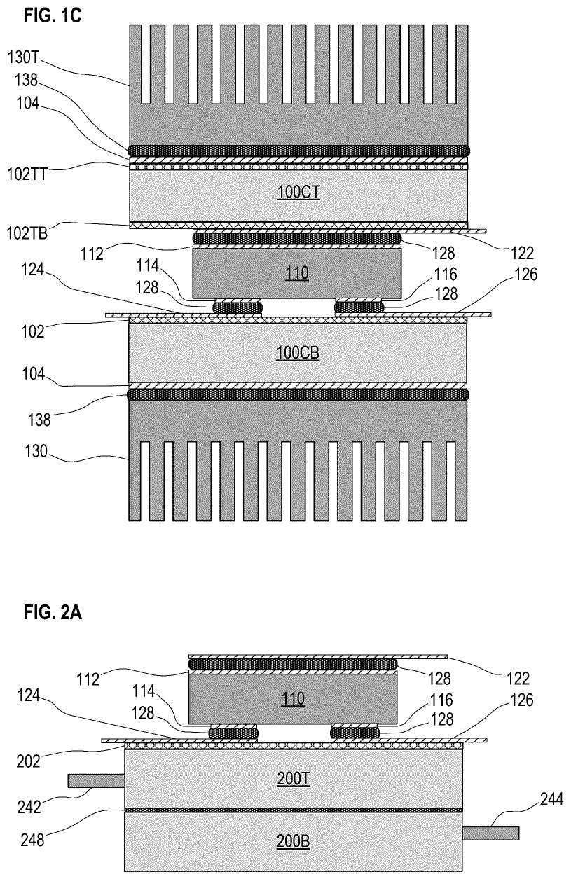

FIG. 1A illustrates an apparatus for cooling a die 110 using a substrate 100A according to an embodiment. The bulk of the substrate 100A may comprise single-crystal 4H SiC.

In embodiments, the bulk of the substrate 100A may have a high electrical resistivity. Accordingly, in embodiments the single-crystal 4H SiC of the substrate 100A may be undoped or may be doped to in such a manner as to not substantially impact the high resistivity of the single-crystal 4H SiC.

In the illustrated embodiment, the die 110 may be a SiC Vertical Metal Oxide Semiconductor Field Effect Transistor (V_MOSFET), and accordingly, the die 110 includes a drain pad 112 disposed on a top of the die 110 and a gate pad 114 and a source pad 116 disposed on a bottom of the die 110. However, embodiments are not limited thereto, and may include one or more dies having different devices therein and/or made of different semiconductor materials (such as silicon).

The composition and structure of the drain pad 112, gate pad 114, and source pad 116 may be as is known in the related arts. Collectively, structures such as the drain pad 112, the gate pad 114, the source pad 116, and the like are referred to herein as pads.

The substrate 100A includes an insulating layer 102 disposed on top of the substrate 100A, and a gate terminal 124 and source terminal 126 each disposed on the insulating layer 102. These terminals may be used to electrically connect the die 110 to circuits not shown in FIG. 1A.

Collectively these and other similar structures disposed on the substrate may be referred to as terminals.

The insulating layer 102 may be used when the substrate 100A may not provide sufficient electrical insulation, and accordingly in some embodiments where the conductivity of the substrate 100A is sufficiently low, the insulating layer 102 may be omitted. The insulating layer 102 may comprise aluminum nitride (AlN), silicon nitride (Si₃N4) or other materials known in the art to be suitable therefor.

In embodiments, the insulating layer 102 may be between 5 and 50 microns thick. As a result, even when the insulating layer 102 has substantially lower thermal conductivity than SiC (for example, 180 W/m-K for AIN or 80 W/m-K for silicon nitride), the insulating layer 102 may have a negligible effect on heat transfer through the substrate 100A.

The substrate 100A may also include a transition layer 104 that facilitates the attachment of a heatsink to the substrate 100A. The composition of the transition layer 104 may vary according to the means used to attach the heatsink as is known in the related art.

The die 110 is mechanically affixed to the substrate 100A by solder 128 disposed between and adhering to the gate terminal 124 and the gate pad 114 and disposed between and adhering to the source terminal 126 and the source pad 116.

A finned heatsink 130 may be mechanically and thermally coupled to the substrate 100A via an attach layer 138. The finned heatsink 130 may comprise materials and configurations as known in the related arts.

The attach layer 138 may be formed by welding, brazing, soldering, diffusion bonding and/or other means known in the related arts, and the composition of the attach layer 138 may be determined by the means used to form it as known in the related arts.

If the CTE of the substrate 100A were substantially different from the CTE of the die 110, then a large temperature change to one or both of the substrate 100A and the die 110 could impose mechanical stresses on the solder 128 and, through the solder 128, to the die 110 as well, which could lead to failure of the die 110, the connections to the die 110, or both.

However, the single-crystal 4H SiC that makes up the bulk of the substrate 100A has a CTE of 2.74×10⁻⁶/° C. at 12° C. and of 4.28×10⁻⁶/° C. at 376° C., which is similar to the CTEs of materials commonly used in dies 110 such as SiC, silicon (Si) (CTE=2.49×10⁻⁶/° C. at 25° C. and 3.61×10⁻⁶/° C. at 227° C.) and Gallium Nitride (GaN) (CTE=3.17×10⁻⁶/° C.).

Accordingly, because the substrate 100A is comprised of a CTE-matched materials (here, single-crystal 4H SiC) failures due to mechanical stresses arising from a CTE mismatch may be prevented.

The CTE of a substrate may be considered matched to the CTE of the die when the two CTEs differ by less than 10% over the entirety of a temperature range of interest, such as the temperature swing of a thermal cycle of a target application. Alternatively, the CTE of a substrate may be considered matched to the CTE of the die when the two CTEs differ by less than 0.30×10⁻⁶/° C. over the entirety of the temperature range of interest.

However, a substrate operating as a cold plate must also have high thermal conductivity, and single-crystal 4H SiC meets this requirement: along the X and Y directions of the SiC crystal, the thermal conductivity is 500 W/m-K at 25° C. and 254 W/m-K at 180° C., while along the Z direction the thermal conductivity is 333 W/m-K at 25° C. and 181 W/m-K at 180° C. For comparison, the thermal conductivity of copper and aluminum, two common cold plate materials, are typically 385 W/m-K and 237 W/m-K, respectively.

FIG. 1B is a cross section of an apparatus for cooling a die using a substrate 100B according to another embodiment. The substrate 100B differs from the substrate 100A of FIG. 1A in that a second insulating layer 102B is disposed on a side of the substrate opposite the side on which the insulating layer 102 is disposed.

FIG. 1C is a cross section of an apparatus for cooling a die using top and bottom substrates 100CT and 100CB according to another embodiment.

The bottom substrate 100CB is essentially identical to the substrate 100A of FIG. 1A, and accordingly a description thereof is omitted for brevity.

The top substrate 100CT is essentially the substrate 100B of FIG. 1B flipped upside-down and disposed on a side of the die 110 opposite the side of the die 110 that the bottom substrate 100CB is disposed on.

Accordingly the top substrate 100CT comprises a bottom insulating layer 102TB disposed on the bottom of the top substrate 100CT and a top insulating layer 102TT disposed on the top of the top substrate 100CT. The drain terminal 122 is disposed on the bottom insulating layer 102TB facing the die 110.

The die 110 is mechanically affixed to the substrate 100CT by solder 128 disposed between and adhering to the drain terminal 122 and the drain pad 112, which thermally couples the die 110 to the top substrate 100CT.

The area of the contact area through which heat passes from a die to a cold plate may be a limiting factor on how well heat can be extracted from the die. Accordingly, by extracting heat from both sides of the die 110 using two SiC substrates having high thermal conductivity, the apparatus of FIG. 1C may substantially improve the extraction of heat from the die 110 compared to single-sided cooling.

However, if the CTE of the top substrate 100CT, the bottom substrate 100CB, or both were substantially different from the CTE of the die 110, then a large temperature change to the substrates, the die 110, or both could cause a dislocation of the relative positions of the terminals and the corresponding pads, which would impose mechanical stress on the solder 128 and/or the die 110 that could lead to device failure. This could be the case if the substrates were made of, for example, copper or aluminum. However, the single-crystal 4H SiC that makes up the bulk of the substrates in this embodiment has a CTE similar to the CTEs of materials commonly used in dies 110, thus rendering the dislocation negligible.

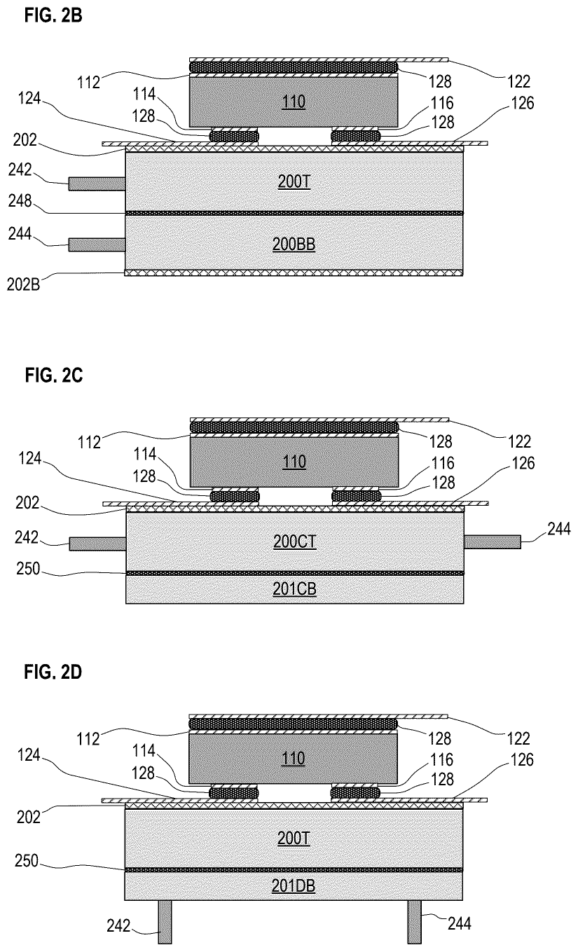

FIG. 2A is a cross section of an apparatus for cooling a die 110 using a substrate comprised of two pieces according to another embodiment. The apparatus of FIG. 2A is similar to the apparatus of FIG. 1A except that, instead of an attached heatsink, a coolant circulated through the substrate is used to remove heat from the substrate. The coolant may comprise water, oil, fluorocarbons, phase-change materials, and the like or mixtures thereof as may be known in the related arts.

Accordingly, to facilitate the formation of channels for the coolant to run through, the substrate comprises a top half substrate 200T and a bottom half substrate 200B joined by a substrate joint 248. The substrate joint 248 may be formed by welding, brazing, soldering, diffusion bonding and/or other means known in the related arts, and the composition of the substrate joint 248 may be determined by the means used to form it as is known in the related arts.

The top half substrate 200T is coupled to the die 110 in a similar manner to the substrate 100A of FIG. 1A and comprises an insulating layer 202 corresponding to the insulating layer 102 of the substrate 100A.

The top half substrate 200T also comprises a fluid inlet 242 configured to provide coolant to the internal channels of the substrate. Although the figures herein illustrate the fluid inlet 242 as a pipe or tube, embodiments are not limited thereto. The fluid inlet 242 may be disposed on the top half substrate 200T using means known in the art.

The bottom half substrate 200B comprises a fluid outlet 244 configured to receive coolant from the internal channels of the substrate. Although the figures herein illustrate the fluid outlet 244 as a pipe or tube, embodiments are not limited thereto. The fluid outlet 244 may be disposed on the bottom half substrate 200B using means known in the art.

The channels in the top half substrate 200T and bottom half substrate 200B are configured to direct the fluid from the fluid inlet 242 to under the die 110 and then out the fluid outlet 244. The channels may include a vapor chamber, fins, grooves, baffles and other such features as may be known in the art.

The fluid may be provided to the fluid inlet 242 from a cooling system external to the apparatus of FIG. 2A, and may be returned to that cooling system from the fluid outlet 244. The cooling system may be any form of fluid-coolant based cooling system such as are known in the related arts.

FIG. 2B is a cross section of an apparatus for cooling a die 110 using a substrate comprised of two halves according to another embodiment.

The apparatus of FIG. 2B differs from the apparatus of FIG. 2A in that the bottom half substrate 200BB of FIG. 2B includes an insulating layer 202B disposed on its bottom that the bottom half substrate 200B of FIG. 2A lacks.

Furthermore, in FIG. 2A the fluid inlet 242 and fluid outlet 244 are arranged on opposite sides of the substrate, whereas in FIG. 2B the fluid inlet 242 and fluid outlet 244 are arranged on the same side of the substrate.

FIG. 2C is a cross section of an apparatus for cooling a die 110 using a substrate according to another embodiment.

The apparatus of FIG. 2C differs from the apparatus of FIG. 2A in that the bottom half of the substrate comprises a substrate cap 201CB that, unlike the bottom half substrate 200B of FIG. 2A, is not comprised of SiC. In various embodiments, the CTE of the substrate cap 201CB may or may not be matched to the CTE of the die 110.

Instead the substrate cap 201CB may be comprised of a metal, ceramic, glass, plastic, or other material known in the art and suitable for containing the coolant within the top half substrate 200CT under the intended operating conditions of the apparatus.

The substrate cap 201CB is joined to the top half substrate 200CT by a cap joint 250 appropriate for the materials involved. These means include methods such as brazing, welding, and the like, but may also include adhesives, gaskets, mechanical fasteners, and the like as may be appropriate for the intended application of the apparatus.

Because the bottom half of the substrates shown in FIGS. 2A-2C are not in the thermal path between the die 110 and the coolant, the apparatus of FIG. 2C may deliver similar cooling performance to the apparatuses of FIGS. 2A and 2B at potentially lower cost. Furthermore, when a removable means such as fasteners and gaskets is used to affix the substrate cap 201CB to the top half substrate 200CT, an ease of maintenance of the coolant system may be improved.

Further differences in the apparatus of FIG. 2C relative to the apparatus of FIG. 2A include that the fluid outlet 244 is disposed on the top half substrate 200CT, which corresponds to the top half substrate 200T of FIG. 2A.

FIG. 2D is a cross section of an apparatus for cooling a die 110 using a substrate according to another embodiment.

The apparatus of FIG. 2D differs from the apparatus of FIG. 2C in that the fluid inlet 242 and fluid outlet 244 are disposed on the substrate cap 201 DB instead of on the top half substrate 200CT, which may reduce the difficulty, cost, or both of manufacturing the apparatus of FIG. 2D relative to the apparatus of FIG. 2C.

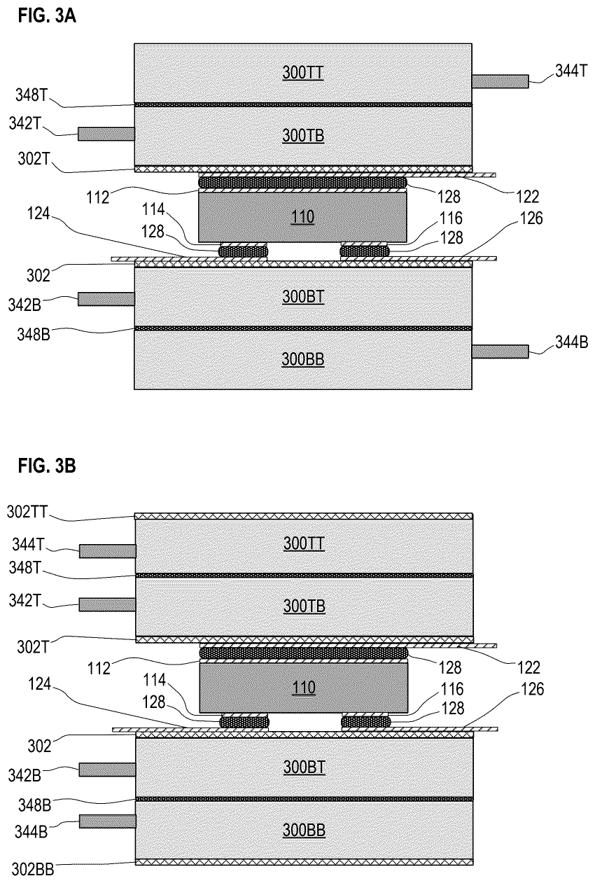

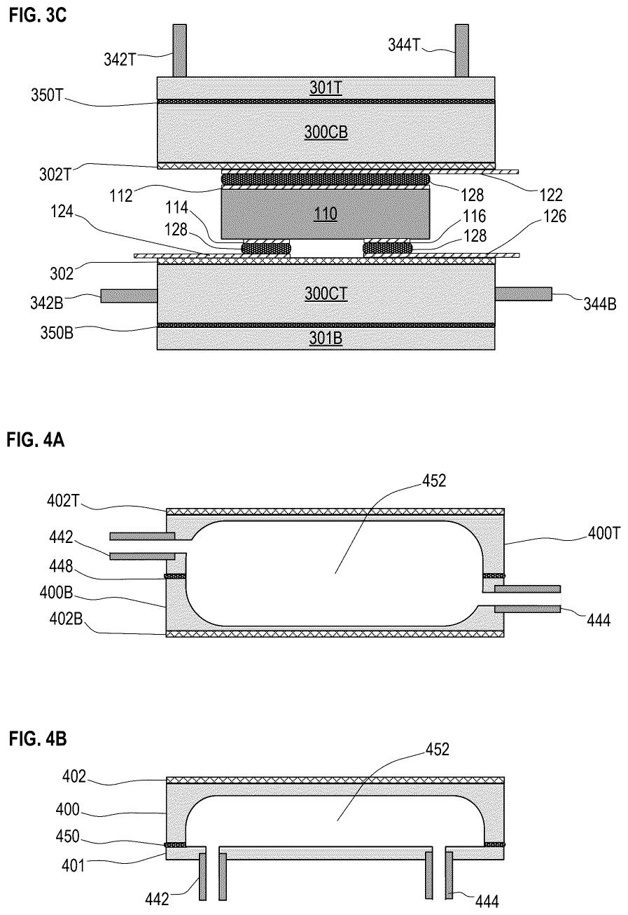

FIG. 3A is a cross section of an apparatus for cooling a die using substrates according to an embodiment. The apparatus of FIG. 3A comprises two substrates each similar to the two-piece substrate shown in FIG. 2A and respectively disposed on opposite sides of the die 110 similarly to as described for the substrates shown in FIG. 1C.

Accordingly, the apparatus of FIG. 3A includes a top substrate comprising a top top half substrate 300TT and a top bottom half substrate 300TB and also includes a bottom substrate comprising a bottom top half substrate 300BT and a bottom bottom half substrate 300BB.

The bottom top half substrate 300BT comprises an insulating layer 302 and corresponds to the top half substrate 200T of FIG. 2A. The bottom bottom half substrate 300BB corresponds to the bottom half substrate 200B of FIG. 2A and is affixed to the bottom top half substrate 300BT by a bottom substrate joint 348B corresponding to the substrate joint 248 of FIG. 2A.

A bottom fluid inlet 342B is disposed on a first side of the bottom top half substrate 300BT and corresponds to the fluid inlet 242 of FIG. 2A.

A bottom fluid outlet 344B is disposed on a second side of the bottom bottom half substrate 300BB and corresponds to the fluid outlet 244 of FIG. 2A.

The top substrate of the apparatus corresponds to an upside-down version of the bottom substrate, and therefore the top insulating layer 302T, top fluid inlet 342T, top fluid outlet 344T, and top substrate joint 348T are respectively disposed and operate in a similar manner to the insulating layer 302, bottom fluid inlet 342B, bottom fluid outlet 344B, and bottom substrate joint 348B.

In embodiments, the coolant provided to the apparatus of FIG. 3A may run in parallel or in series through the top and bottom substrates. In other embodiments, each of the top substrate and the bottom substrate may respectively be provided separate coolant by separate cooling systems, which may provide redundancy.

The apparatus of FIG. 3A provides the advantages of double-sided cooling described with respect to FIG. 1C. The apparatus of FIG. 3A comprises two substrates each similar to the two-piece substrate shown in FIG. 2A and respectively disposed on opposite sides of the die 110 similarly as described for the substrates shown in FIG. 1C

FIG. 3B is a cross section of an apparatus for cooling a die 110 using substrates according to another embodiment.

The apparatus of FIG. 3B differs from the apparatus of FIG. 3A in that additional insulating layers 302BB and 302TT are respectively provided on the bottom substrate and top substrate. Furthermore, the fluid outlets 344B and 344T are disposed on the same side of the apparatus as the fluid inlets 342B and 342T, as opposed to being disposed on opposite sides as shown in FIG. 3A.

FIG. 3C is a cross section of an apparatus for cooling a die using substrates according to another embodiment.

The apparatus of FIG. 3C differs from the apparatus of FIG. 3A in that the top top half substrate 300TT and the bottom bottom half substrate 300BB of FIG. 3A have been respectively replaced by a top substrate cap 301T and a bottom substrate cap 301B. The top substrate cap 301T and a bottom substrate cap 301B are joined to the top bottom half substrate 300CB and the bottom top half substrate 300CT by top and bottom cap joints 350T and 350B, respectively.

The apparatus of FIG. 3C also differs from the apparatus of FIG. 3A in how the fluid inlets and outlets are disposed. In FIG. 3C, the bottom fluid inlet 342B and the bottom fluid outlet 344B are disposed on respective sides of the bottom top half substrate 300CT, and the top fluid inlet 342T and the top fluid outlet 344T are disposed on a top side of the top substrate cap 301T.

FIG. 4A is a cut-away cross section of an apparatus for cooling a die using a substrate according to an embodiment.

The apparatus of FIG. 4A comprises a top half substrate 400T and a bottom half substrate 400B, both comprised of single-crystal 4H SiC. Top and bottom insulating layers 402T and 402B are disposed on the top and bottom half substrates 400T and 400B, respectively. The top half substrate 400T and bottom half substrate 400B are coupled together by a substrate joint 448 as previously described.

The apparatus further comprises a fluid inlet 442 and a fluid outlet 444 that respectively provide and receive coolant to a cavity 452 disposed within the substrates. The cavity 452 may be formed in the substrates using etching, micromachining, or other techniques known in the related arts.

Thermal energy from devices mounted on one or both sides of the apparatus of FIG. 4A is conveyed by the top half substrate 400T, the bottom half substrate 400B, or both to the coolant in the cavity 452. Accordingly, the cavity 452 may include fins, grooves, baffles, channels, and the like to enhance the transfer of thermal energy from the top half substrate 400T, the bottom half substrate 400B, or both to the coolant in the cavity 452.

FIG. 4B is a cross section of an apparatus for cooling a die using a substrate according to another embodiment. The apparatus of FIG. 4B differs from the apparatus of FIG. 4A in that the bottom half substrate 400B is replaced by as substrate cap 401, which may be comprised of materials other than SiC, as previously discussed. The apparatus of FIG. 4B also differs from the apparatus of FIG. 4A in that the cavity 452 does not extend into the substrate cap 401, but embodiments are not limited thereto.

Although not shown in FIG. 4B, fins, grooves, channels, baffles and the like may be disposed on the substrate cap 401 to enhance the transfer of thermal energy to the coolant.

Embodiments provide reduced thermal-cycling-induced mechanical stress to one or more devices (such as dies) mounted on a cold plate by having the CTE of a substrate of the cold plate match the CTE of the one or more devices.

Embodiments may also be mounted to opposite sides (i.e., top and bottom sides) of a die to provide double-sided cooling without subjecting the die to unacceptable levels of thermal-cycling-induced mechanical stress.

In embodiments, substrates of the cold plates comprise 4H Single-Crystal Silicon Carbide (SiC). The 4H Single-Crystal SiC may comprise a substantial majority of the substrate.

In embodiments, the substrates may provide electrical insulation to the devices. The electrical insulation may be provided via the inherent low conductivity of the substrate or via an insulating layer formed on the substrate, which insulating layer may be formed using processes for forming insulating layers in SiC such as may be known in the related arts.

Aspects of the present disclosure have been described in conjunction with the specific embodiments that are presented as illustrative examples, but embodiments are not limited to those shown in the drawings or those mentioned in the accompanying text. Numerous alternatives, modifications, and variations to the disclosed embodiments may be made without departing from the scope of the claims set forth below. Embodiments disclosed herein are not intended to be limiting.

1. An apparatus for cooling a semiconductor die, the apparatus comprising:
a first substrate mechanically coupled to the semiconductor die and configured to extract thermal energy from the die and provide electrical insulation to the die,
wherein a coefficient of linear thermal expansion (CTE) of the first substrate is similar to a CTE of the semiconductor die, and
wherein the first substrate comprises crystalline silicon carbide.

2. The semiconductor device of claim 1, wherein two CTEs are considered similar when a difference between the two CTEs is 10% or less over an entire target operating temperature range of the semiconductor device.

3. The semiconductor device of claim 1, wherein two CTEs are considered similar when a difference between the two CTEs is 0.30×10⁻⁶/° C. or less over an operating temperature range of the semiconductor device.

4. The apparatus of claim 1, wherein the first substrate comprises single-crystal 4H silicon carbide.

5. The apparatus of claim 1, further comprising:
a heatsink disposed on the first substrate.

6. The apparatus of claim 1, further comprising:
a first electrically-insulating layer disposed on a first side the first substrate.

7. The apparatus of claim 1, further comprising:
a second electrically-insulating layer disposed on a second side the first substrate, wherein the second side is opposite the first side.

8. The apparatus of claim 1, further comprising:
a fluid inlet configured to provide a fluid to a cavity disposed within the first substrate, and
a fluid outlet configured to receive the fluid from the cavity.

9. The apparatus of claim 8, further comprising:
a second substrate disposed on the first substrate,
wherein the bulk of the first substrate comprises single-crystal 4H silicon carbide,
wherein the bulk of the second substrate comprises single-crystal 4H silicon carbide, and
wherein the cavity extends into the second substrate.

10. The apparatus of claim 9, further comprising:
a first electrically-insulating layer disposed on the first substrate, and
a second electrically-insulating layer disposed on the second substrate.

11. The apparatus of claim 8, further comprising:
a substrate cap disposed on the first substrate,
wherein the material comprising the bulk of the substrate cap is different from the material comprising the bulk of the first substrate.

12. The apparatus of claim 11,
wherein the fluid inlet, the fluid outlet, or both are disposed on the substrate cap.

13. The apparatus of claim 11,
wherein the cavity extends into the substrate cap.

14. The apparatus of claim 1, further comprising:
a second substrate mechanically coupled to the semiconductor die and configured to extract thermal energy from the die,
wherein the first substrate is disposed on a first side of the die,
wherein the second substrate is disposed on a second side of the die,
wherein the bulk of the first substrate comprises single-crystal 4H silicon carbide,
wherein the bulk of the second substrate comprises single-crystal 4H silicon carbide, and
wherein the first side is opposite the second side.

15. The apparatus of claim 14, further comprising:
a first heatsink disposed on the first substrate, and
a second heatsink disposed on the second substrate.

16. The apparatus of claim 14, further comprising:
a first cavity disposed in the first substrate;
a first fluid inlet configured to provide a first fluid to the first cavity;
a first fluid outlet configured to receive the first fluid from the first cavity;
a second cavity disposed in the second substrate;
a second fluid inlet configured to provide a second fluid to the second cavity;
a second fluid outlet configured to receive the second fluid from the second cavity.

17. The apparatus of claim 16, further comprising:
a third substrate disposed on the first substrate,
wherein the bulk of the third substrate comprises single-crystal 4H silicon carbide, and
wherein the first cavity extends into the third substrate.

18. The apparatus of claim 16, further comprising:
a substrate cap disposed on the first substrate,
wherein the material comprising the bulk of the substrate cap is different from the material comprising the bulk of the first substrate.

19. The apparatus of claim 18,
wherein the fluid inlet, the fluid outlet, or both are disposed on the substrate cap.

20. The apparatus of claim 18,
wherein the cavity extends into the substrate cap.

21. The apparatus of claim 10, wherein the first electrically-insulating layer, the second insulating layer, or both comprise silicon carbide having a low electrical conductivity.

22. The apparatus of claim 6, wherein the first electrically-insulating layer comprises silicon carbide having a low electrical conductivity.
